(19) United States
(12) Patent Application Publication
(10) Pub. No.: US 2025/0150078 A1
(43) Pub. Date: May 8, 2025

(54) POWER TOOL INCLUDING A TRIGGER WITH A NON-CONTACT SENSOR

(71) Applicant: MILWAUKEE ELECTRIC TOOL CORPORATION, Brookfield, WI (US)

(72) Inventors: Mitchell A. Ellena, West Allis, WI (US); David A. Bierdeman, New Berlin, WI (US); Marcus Wechselberger, Milwaukee, WI (US); Ryan Khatib, Waukesha, WI (US); Kirat S. Mokha, Milwaukee, WI (US); Noah P. Seiler, Milwaukee, WI (US); Jason M. Julius, Waukesha, WI (US); Ivan N. Zozulya, Waukesha, WI (US); Nikita Bhatt, Chicago, IL (US); Robert J. Visher, Downers Grove, IL (US); Caleb M. Schober, Milwaukee, WI (US); Ian Spayer, Berwyn, IL (US)

(21) Appl. No.: 18/938,214

(22) Filed: Nov. 5, 2024

Related U.S. Application Data
(60) Provisional application No. 63/679,966, filed on Aug. 6, 2024.
(60) Provisional application No. 63/596,829, filed on Nov. 7, 2023.

(51) Int. Cl. H03K 17/95; B25C 1/06; G01D 5/14; G01R 33/07; G01R 33/09; H03K 17/97

(52) U.S. Cl. CPC H03K 17/9517; G01D 5/145; G01R 33/072; G01R 33/098; H03K 17/97; B25C 1/06; H03K 2017/9706

(57) ABSTRACT

A power tool including a housing, a trigger disposed on an outside of the housing, the trigger including a magnet, a motor within the housing, the motor configured to produce a rotational output to a drive mechanism, a Hall effect sensor configured to sense a position of the trigger based on a proximity of the magnet to the Hall effect sensor, and an electronic controller connected to the Hall effect sensor. The electronic controller is configured to determine the position of the trigger based on a signal from the Hall effect sensor and control the drive mechanism based on the position of the trigger.

### RELATED APPLICATIONS

This application claims the benefit of U.S. Provisional Patent Application No. 63/596,829, filed on Nov. 7, 2023, and of U.S. Provisional Patent Application No. 63/679,966, filed on Aug. 6, 2024, the entire content of each of which is hereby incorporated by reference.

### FIELD

Embodiments described herein relate to power tools.

### SUMMARY

Power tools described herein include a housing, a trigger disposed on an outside of the housing and including a magnet, a motor within the housing, the motor configured to produce a rotational output to a drive mechanism, a Hall effect sensor configured to sense a position of the trigger based on a proximity of the magnet to the Hall effect sensor, and an electronic controller connected to the Hall effect sensor. The electronic controller is configured to determine the position of the trigger based on a signal from the Hall effect sensor, and control the drive mechanism based on the position of the trigger.

In some aspects, the position is one of a depressed position or a released position.

In some aspects, the Hall effect sensor is a digital Hall effect sensor.

In some aspects, the Hall effect sensor is configured to sense a varying amount of magnetic flux based on the position of the Hall effect sensor relative to the magnet.

In some aspects, in response to the trigger being in the depressed position, the electronic controller is configured to control the drive mechanism to initiate a firing operation of the power tool.

In some aspects, when the trigger is in the depressed position, the Hall effect sensor does not detect the magnet.

Power tools described herein include a housing, a trigger disposed on an outside of the housing and including a metal target portion, and a motor within the housing. The motor is configured to produce a rotational output to a drive mechanism, an inductive sensor is configured to sense a position of the trigger based on a voltage produced in the sensor by the metal target portion, and an electronic controller connected to the inductive sensor. The electronic controller is configured to determine the position of the trigger based on a signal from the inductive sensor and control the drive mechanism based on the position of the trigger.

In some aspects, the position of the trigger is one of a depressed position or a released position.

In some aspects, the current is induced in the metal target portion when the trigger is moved to the depressed position.

In some aspects, in response to the trigger being in the depressed position, the electronic controller controls the power tool to initiate a firing operation of the power tool.

In some aspects, the inductive sensor is disposed on a bottom of a printed circuit board.

In some aspects, the trigger is configured to pivot with respect to the inductive sensor.

In some aspects, the inductive sensor is a binary inductive sensor configured to sense an induced current in response to the target portion of the trigger being moved toward the inductive sensor.

In some aspects, in response to the inductive sensor detecting the induced current, the inductive sensor is configured to transmit a signal to the controller indicating that the trigger is depressed.

Power tools described herein include a housing, a trigger, a motor, a tunnel magnetoresistance (“TMR”) sensor, and an electronic controller. The trigger is disposed on an outside of the housing, the trigger including a magnet connected to the trigger. The motor is within the housing. The motor is configured to produce a rotational output to a drive mechanism. The TMR sensor is configured to sense a position of the trigger based on a signal produced by the TMR sensor related to a position of the magnet. The electronic controller is connected to the TMR sensor. The electronic controller is configured to determine the position of the trigger based on the signal produced by the TMR sensor, and control the drive mechanism based on the position of the trigger.

In some aspects, the position is one of a depressed position or a released position.

In some aspects, the TMR sensor includes an insulator layer between a pin ferromagnetic layer and a free ferromagnetic layer.

In some aspects, the TMR sensor is configured to sense a first magnetization direction of the pin ferromagnetic layer and a second magnetization direction of the free ferromagnetic layer, and wherein, when the first magnetization direction and the second magnetization direction are opposite, a sensed resistance of the TMR sensor is at a maximum value.

In some aspects, when the trigger is in the depressed position, the sensed resistance of the TMR sensor is at the maximum value.

In some aspects, the TMR sensor includes a lead configured to provide the sensed resistance to the electronic controller.

Before any embodiments are explained in detail, it is to be understood that the embodiments are not limited in application to the details of the configurations and arrangements of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Accordingly, in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

Other aspects of the embodiments will become apparent by consideration of the detailed description and accompanying drawings.

### BRIEF DESCRIPTION OF THE DRAWINGS

FIG. 1 illustrates a power tool, according to some embodiments.

FIG. 2 illustrates a partial cross-sectional view of the power tool of FIG. 1.

FIG. 3 illustrates a control system for the power tool of FIG. 1, according to some embodiments.

FIG. 4A is a schematic view of the power tool of FIG. 1 illustrating a driver blade in a driven or bottom-dead-center position.

FIG. 4B is a schematic view of the power tool of FIG. 1 illustrating a driver blade in an undriven or top-dead-center position prior to actuation.

FIGS. 5A and 5B illustrate a user interface for the power tool of FIG. 1, according to some embodiments.

FIG. 6 is a flow chart of a method for sensing a trigger position in the power tool of FIG. 1, according to some embodiments.

FIGS. 7A and 7B illustrate a user interface for the power tool of FIG. 1, according to some embodiments.

FIG. 8 is a flow chart of a method for sensing a trigger position in the power tool of FIG. 1, according to some embodiments.

FIGS. 9A and 9B show a user interface for the power tool of FIG. 1, according to some embodiments.

FIG. 9C shows a circuit board for the power tool of FIG. 1, according to some embodiments.

FIG. 9D shows a sensing portion of the circuit board of FIG. 9C, according to some embodiments.

FIG. 10 is a flow chart of a method for sensing a trigger position in the power tool of FIG. 1, according to some embodiments.

FIGS. 11A and 11B show a user interface for the power tool of FIG. 1, according to some embodiments.

FIG. 12 is a flow chart of a method for sensing a trigger position in the power tool of FIG. 1, according to some embodiments.

FIGS. 13A and 13B show a user interface for the power tool of FIG. 1, according to some embodiments.

FIG. 14 is a flow chart of a method for sensing a trigger position in the power tool of FIG. 1, according to some embodiments.

FIGS. 15A and 15B show a user interface for the power tool of FIG. 1, according to some embodiments.

FIG. 15C shows a circuit board for the power tool of FIG. 1, according to some embodiments.

FIG. 16 is a flow chart of a method for sensing a trigger position in the power tool of FIG. 1, according to some embodiments.

### DETAILED DESCRIPTION

Embodiments described herein relate to a power tool, such as, for example, a fastener driver or nailer, including a sensor located in a handle of the power tool. In some embodiments, the sensor can be a linear magnetic sensor that is configured to sense a varying amount of magnetic flux based on the proximity of the magnetic sensor to a magnet located in the housing. In some embodiments, the sensor can be an inductive sensor configured to sense an induced current as a target of a trigger is moved along a length of the sensor.

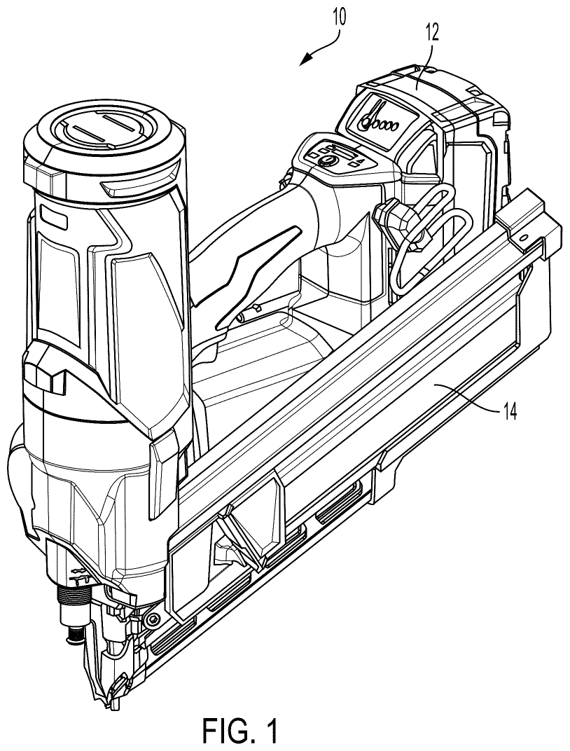

FIG. 1 illustrates a power tool 10, such as a fastener driver or nailer 10 (e.g., a gas spring-powered nailer), that is operable to drive fasteners (e.g., single-headed nails, double-headed or duplex nails, tacks, staples, etc.) held within a magazine 14 into a workpiece. The power tool 10 is powered by a removable and rechargeable battery pack 12.

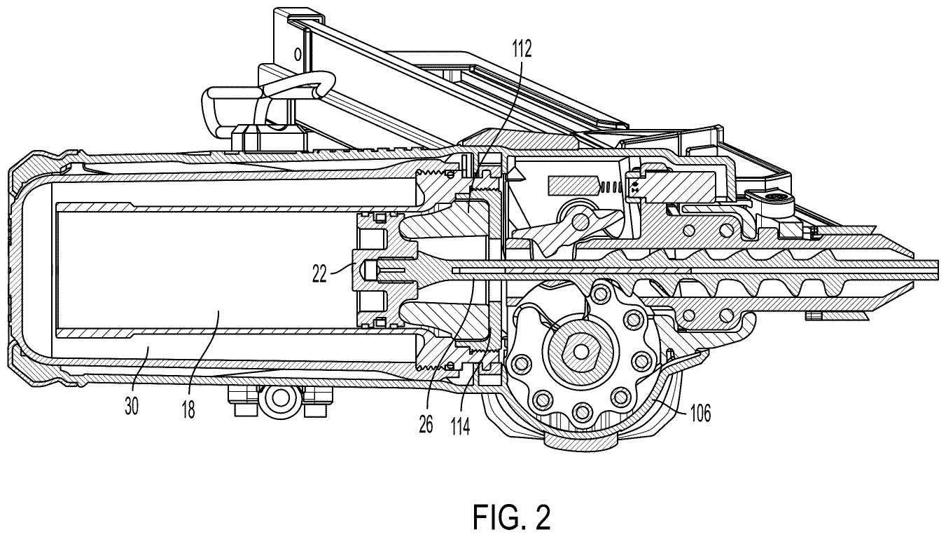

With reference to FIG. 2, the power tool 10 does not require an external source of air pressure, but rather includes an outer storage chamber cylinder 30 of pressurized gas in fluid communication with a cylinder 18. In the illustrated embodiment, the cylinder 18 and moveable piston 22 are positioned within the storage chamber cylinder 30. The power tool 10 includes a bumper 112 that is positioned beneath the piston 22 to stop the piston 22 at a driven position and to absorb the impact energy from the piston 22. The bumper 112 is configured to distribute the impact force of the piston 22 uniformly throughout the bumper 112 as the piston 22 is rapidly decelerated upon reaching a driven position (i.e., a bottom dead center position). The bumper 112 is disposed in the cylinder 18 and is clamped into place by a drive mechanism or a lifter housing portion 106, which is threaded to the bottom end of the cylinder 18. As shown, the bumper 112 is received within a cutout 114 that is formed in the lifter housing portion 106. The cutout 114 coaxially aligns the bumper 112 relative to a striker or driver blade 26. Although the term driver blade is used herein, the term striker can be interchangeably used in place of driver blade. The driver blade 26 is configured to move with the piston 22 along the same path of motion (e.g., from top dead center to bottom dead center).

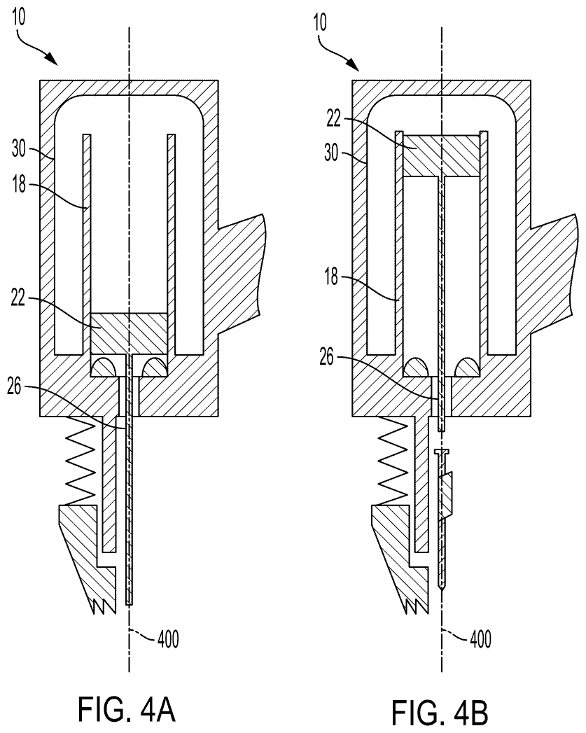

As shown in FIG. 2, the storage chamber cylinder 30 is concentric with the cylinder 18. The cylinder 18 has an annular inner wall that guides the piston 22 and the driver blade 26 along a driving axis 400 (see FIGS. 4A and 4B) to compress the gas in the storage chamber cylinder 30. The storage chamber cylinder 30 has an annular outer wall circumferentially surrounding the inner wall. The cylinder 18 has a threaded section and the storage chamber cylinder 30 has corresponding threads at a lower end of the storage chamber cylinder 30 such that the cylinder 18 is threadably coupled to the storage chamber cylinder 30 at the lower end. As such, the cylinder 18 is configured to be axially secured to the storage chamber cylinder 30

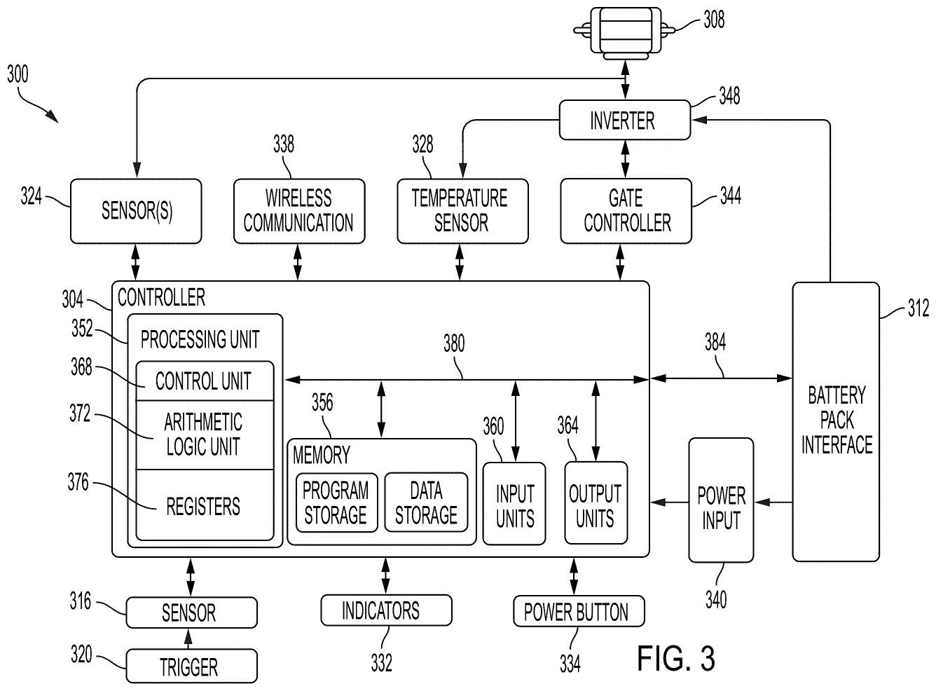

FIG. 3 illustrates a control system 300 for the power tool 10. The control system 300 includes a controller 304. The controller 304 is electrically and/or communicatively connected to a variety of modules or components of the power tool 10. For example, the illustrated controller 304 is electrically connected to a motor 308 (e.g., a brushless motor), a battery pack interface 312, one or more sensors 316 (connected to a trigger 320 disposed on an outside of the housing), one or more additional sensors 324 (e.g., current sensors, position sensors, voltage sensors, etc.), a temperature sensor 328, a wireless communication controller 338, one or more indicators 332, a power button 334, a power input module 340, and a gate controller 344 (connected to an inverter 348). The motor 308 includes a rotor, a stator, and a shaft that rotates about a longitudinal axis.

The controller 304 includes combinations of hardware and software that are operable to, among other things, control the operation of the power tool 10, monitor the operation of the power tool 10, activate the one or more indicators 332 (e.g., an LED), etc. The gate controller 344 is configured to control the inverter 348 to convert a DC power supply to phase signals for powering the phases of the motor 308. The current sensor 324 is configured to, for example, sense a current between the inverter 348 and the motor 308. The temperature sensor 328 is configured to, for example, sense a temperature of the inverter 348. In some implementations, the temperature sensor 328 is configured to, for example, sense a temperature of the rechargeable battery pack 12.

The controller 304 includes a plurality of electrical and electronic components that provide power, operational control, and protection to the components and modules within the controller 304 and/or the power tool 10. For example, the controller 304 includes, among other things, a processing unit 352 (e.g., a microprocessor, a microcontroller, an electronic controller, an electronic processor, or another suitable programmable device), a memory 356, input units 360, and output units 364. The processing unit 352 includes, among other things, a control unit 368, an arithmetic logic unit (“ALU”) 372, and a plurality of registers 376 (shown as a group of registers in FIG. 3), and is implemented using a known computer architecture (e.g., a modified Harvard architecture, a von Neumann architecture, etc.). The processing unit 352, the memory 356, the input units 360, and the output units 364, as well as the various modules or circuits connected to the controller 304 are connected by one or more control and/or data buses (e.g., common bus 380). The control and/or data buses are shown generally in FIG. 3 for illustrative purposes. The use of one or more control and/or data buses for the interconnection between and communication among the various modules, circuits, and components would be known to a person skilled in the art in view of the invention described herein.

The memory 356 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 352 is connected to the memory 356 and executes software instructions that are capable of being stored in a RAM of the memory 356 (e.g., during execution), a ROM of the memory 356 (e.g., on a generally permanent basis), or another non-transitory computer readable medium such as another memory or a disc. Software included in the implementation of the power tool 10 can be stored in the memory 356 of the controller 304. The software includes, for example, firmware, one or more applications, program data, filters, rules, one or more program modules, and other executable instructions. The controller 304 is configured to retrieve from the memory 356 and execute, among other things, instructions related to the control processes and methods described herein. In other constructions, the controller 304 includes additional, fewer, or different components.

The battery pack interface 312 includes a combination of mechanical components (e.g., rails, grooves, latches, etc.) and electrical components (e.g., one or more terminals) configured to and operable for interfacing (e.g., mechanically, electrically, and communicatively connecting) the power tool 10 with a battery pack. For example, power provided by the battery pack to the nailer is provided through the battery pack interface 312 to the power input module 340. The power input module 340 includes combinations of active and passive components to regulate or control the power received from the battery pack prior to power being provided to the controller 304. The battery pack interface 312 also supplies power to the inverter 348 to be switched by the switching FETs to selectively provide power to the motor 308. The battery pack interface 312 also includes, for example, a communication line 384 to provide a communication line or link between the controller 304 and the battery pack.

The indicators 332 include, for example, one or more light-emitting diodes (“LEDs”). The indicators 332 can be configured to display conditions of, or information associated with, the power tool 10. For example, the indicators 332 are configured to indicate measured electrical characteristics of the power tool 10, the status of the device, etc. The one or more user input modules 340 may be operably coupled to the controller 304 to, for example, select a forward mode of operation or a reverse mode of operation, a torque and/or speed setting for the power tool 10 (e.g., using torque and/or speed switches), etc.

The controller 304 may be configured to determine whether a fault condition of the power tool 10 is present and generate one or more control signals related to the fault condition. For example, the controller 304 may calculate or include, within memory 356, predetermined operational threshold values and limits for operation of the power tool 10. For example, when a potential thermal failure (e.g., of a FET, the motor 308, etc.) is detected or predicted by the controller 304, power to the motor 308 can be limited or interrupted until the potential for thermal failure is reduced. If the controller 304 detects one or more such fault conditions of the nailer or determines that a fault condition of the power tool 10 no longer exists, the controller 304 may be configured to provide information and/or control signals to another component of the power tool 10 (e.g., the battery pack interface 312, the indicators 332, etc.). The signals can be configured to, for example, trip or open a high impedance trace of the nailer, reset a switch, etc.

The controller 304 may be configured to determine a state-of-charge (“SOC”) the rechargeable battery pack 12. The controller 304 may also be configured to receive signals from a monitoring circuit (e.g., including sensors 324, etc.) that is configured to sense the SOC level or voltage value, of battery cells of the rechargeable battery pack 12, and transmit the voltage readings to the controller 304. The voltage level of the battery cells may be determined by, for example, measuring the total open circuit voltage of the battery cells or by summing the voltage measurements of each battery cell. In some embodiments, the monitoring circuit is additionally configured to sense a discharge current of the battery cells (e.g., using a current sensor) and/or a temperature of the rechargeable battery pack 12 (e.g., using a temperature sensor) and transmit the sensed current and/or temperature readings to the controller 304. The monitoring circuit is further configured to receive commands from the controller 304 during operation of the power tool 10. In some embodiments, the SOC, a sensed current, and or a sensed temperature, of the rechargeable battery pack 12 is determined by the battery pack 12 and communicated to the controller 304.

FIGS. 4A and 4B illustrate a partial section view of the power tool 10. As previously described with respect to FIG. 2, the power tool 10 includes the cylinder 18 and the piston 22 positioned within outer storage chamber cylinder 30. The piston 22 is configured to drive the driver blade 26. The power tool 10 does not require an external source of air pressure, and instead includes the outer storage chamber cylinder 30 of pressurized fluid (e.g., gas) in communication with the cylinder 18. The driver blade 26 defines a driving axis 400. During a driving cycle, the driver blade 26 and the piston 22 are moveable between a top-dead-center (“TDC”) position (as shown in FIG. 4B) and a driven or bottom-dead-center (“BDC”) position (as shown in FIG. 4A).

In operation, the lifter housing portion 106 drives the piston 22 and the driver blade 26 toward the TDC position by energizing the motor 308. As the piston 22 and the driver blade 26 are driven toward the TDC position, the gas above the piston 22 and the gas within the storage chamber cylinder 30 is compressed. Prior to reaching the TDC position, the motor 308 is deactivated and the piston 22 and the driver blade 26 are held in a ready position, which is located between the TDC and the BDC positions, until being released by, for example, user activation of the trigger 320. When released, the compressed gas above the piston 22 and within the storage chamber cylinder 30 drives the piston 22 and the driver blade 26 to the driven position, thereby initiating a firing operation and driving a fastener into the workpiece. The illustrated power tool 10 therefore operates on a gas spring principle utilizing the lifter housing portion 106 and the piston 22 to further compress the gas within the cylinder 18 and the storage chamber cylinder 30.

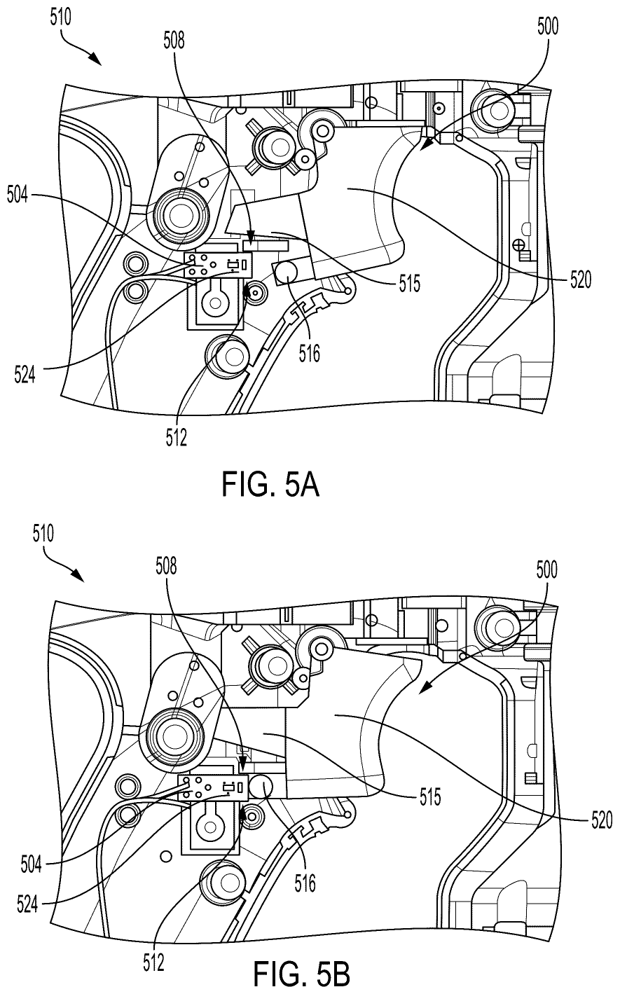

FIGS. 5A and 5B show a first embodiment of a user interface 500 for a power tool 510 (e.g., power tool 10). The user interface 500 includes a circuit board 504 and a trigger 520 (e.g., trigger 320) of the power tool 510. The trigger 520 is disposed adjacent to a side 508 of the circuit board 504 and is configured to be depressed by a user. When depressed, the trigger 520 moves a magnet 516 attached to the trigger 520 near a trigger sensing portion 512 of the circuit board 504. A trigger return spring 515 is configured to return the trigger 520 to an undepressed position when the trigger 520 is not being depressed. Although a pivoting trigger is shown, embodiments including non-pivoting triggers (e.g., linear translation triggers) are contemplated.

The sensing portion 512 includes a magnetic sensor (e.g., a Hall effect sensor) 524. The trigger 520 includes the magnet 516 attached to an outer end of the trigger 520. The Hall effect sensor 524 is located within the power tool 510 such that when the trigger 520 is actuated, the magnet 516 is sensed by the Hall effect sensor 524. The magnetic sensor 524 can be a linear magnetic sensor 524 that will sense a varying amount of magnetic flux based on the proximity of the magnetic sensor 524 to the magnet 516. When the magnetic sensor 524 senses that the magnet 516 is in close proximity to the magnetic sensor 524, the magnetic sensor 524 transmits a signal to the controller 304 to determine that the trigger 520 is depressed, and a firing operation of the power tool 510 is initiated. In some embodiments, the magnetic sensor 524 is a digital Hall effect sensor 524. The digital Hall effect sensor can output a digital signal (e.g., a pulse-width modulated [“PWM” ] signal) based on the amount of detected magnetic flux from the magnet 516. In other embodiments, the magnetic sensor 524 is an analog Hall effect sensor that outputs an analog signal. In some embodiments, the magnetic sensor 524 is connected to the trigger 520 and the magnet 516 is connected to the circuit board 504 or the housing of the power tool 510.

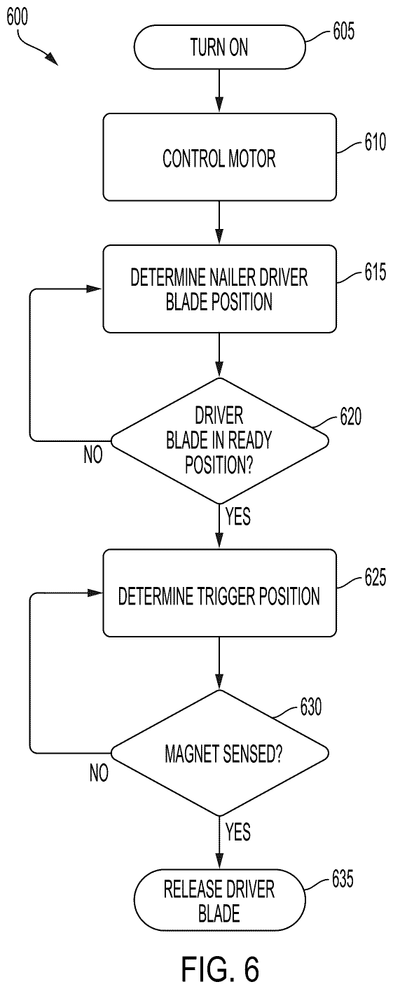

FIG. 6 is a flow chart of a method 600 for sensing the trigger 520 position for controlling the power tool 510 (e.g., initiating the firing operation of the power tool 10). The method 600 begins when the power tool 10 is turned on (BLOCK 605). The controller 304 is configured to execute the method 600, and begins to control the motor 308 based on power received from the battery pack 12 (BLOCK 610). In some embodiments, the motor 308 is stationary until a firing operation is initiated. The controller 304 is configured to determine the position of the nailer driver blade 26 (BLOCK 615) based on, for example, a sensed position of the driver blade 26 (e.g., based on motor rotational position, a sensor that directly detects the position of the driver blade 26, etc.). If the position of the driver blade 26 is determined to be in the ready position (e.g., BDC) (BLOCK 620), the controller is configured to determine a position of the trigger 520 position (BLOCK 615) based on a sensed position of the magnet 516. If the magnet 516 is not sensed, the method 600 returns to BLOCK 625 to determine the position of the trigger 520. If the trigger 520 is determined to be depressed at BLOCK 630, the controller 304 generates a command to release the driver blade 26 (BLOCK 635).

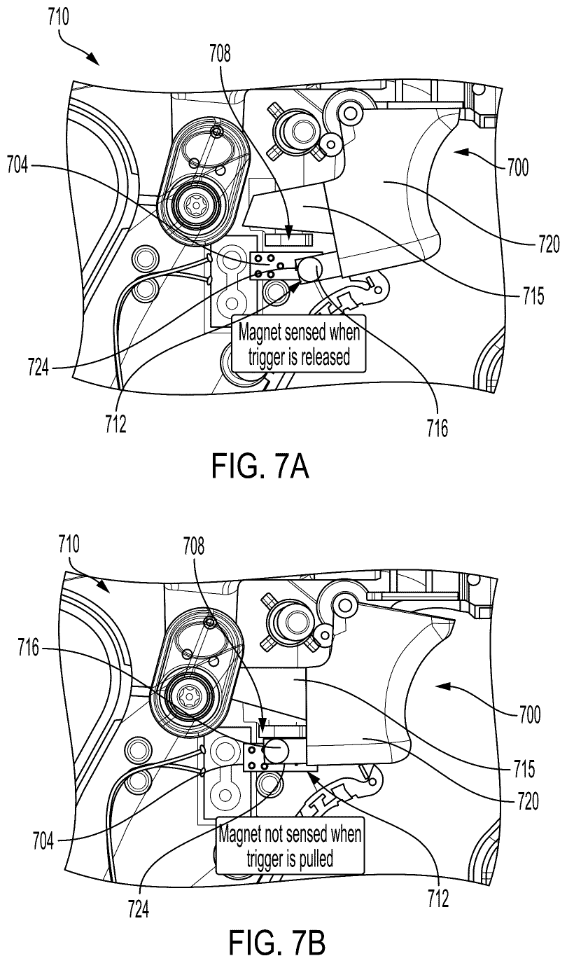

FIGS. 7A and 7B show an embodiment of a user interface 700 for a power tool 710 (e.g., power tool 10). The user interface 700 includes a circuit board 704 and a trigger 720 (e.g., trigger 320) of the power tool 710. The trigger 720 is disposed adjacent to a side 708 of the circuit board 704. When depressed, the trigger 720 moves a magnet 716 attached to the trigger 720 away from a trigger sensing portion 712 of the circuit board 704. A trigger return spring 715 is configured to return the trigger 720 to an undepressed position when the trigger 720 is not being depressed. Although a pivoting trigger is shown, embodiments including non-pivoting triggers (e.g., linear translation triggers) are contemplated.

The sensing portion 712 includes a magnetic sensor (e.g., a Hall effect sensor) 724. The trigger 720 includes the magnet 716 attached to an outer end of the trigger 720. The Hall effect sensor 724 is located within the power tool 710 such that when the trigger 720 is not actuated, the magnet 716 is sensed by the Hall effect sensor 724. The magnetic sensor 724 can be a linear magnetic sensor 724 that will sense a varying amount of magnetic flux based on the proximity of the magnetic sensor 724 to the magnet 716. When the magnetic sensor 724 does not sense that the magnet 716 is in close proximity to the magnetic sensor 724, the magnetic sensor 724 transmits a signal to the controller 304 to determine that the trigger 720 is depressed, and a firing operation of the power tool 710 is initiated. In some embodiments, the magnetic sensor 724 is a digital Hall effect sensor 724. The digital Hall effect sensor can output a digital signal (e.g., a pulse-width modulated [“PWM” ] signal) based on the amount of detected magnetic flux from the magnet 716. In some embodiments, the magnetic sensor 724 is connected to the trigger 720 and the magnet 716 is connected to the circuit board 704 or the housing of the power tool 710.

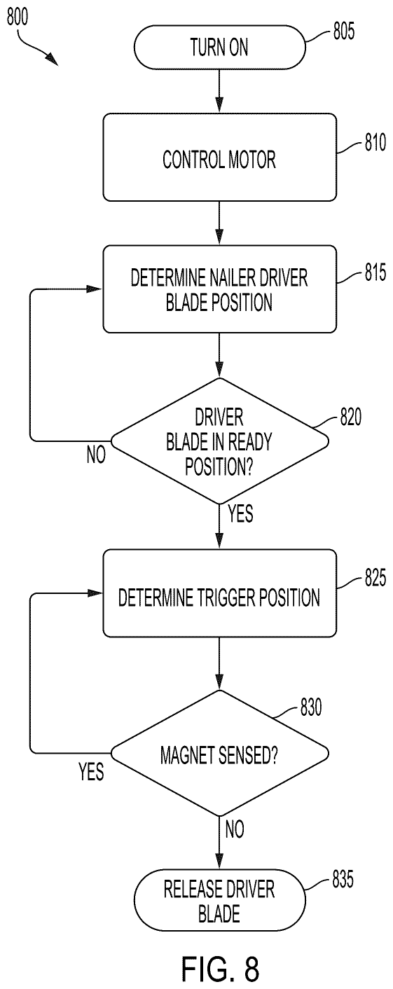

FIG. 8 is a flow chart of a method 800 for sensing the trigger 720 position for controlling the power tool 710 (e.g., initiating the firing operation of the power tool 10). The method 800 begins when the power tool 10 is turned on (BLOCK 805). The controller 304 is configured to execute the method 800, and begins to control the motor 308 based on power received from the battery pack 12 (BLOCK 810). In some embodiments, the motor 308 is stationary until a firing operation is initiated. The controller 304 is configured to determine the position of the nailer driver blade 26 (BLOCK 815) based on, for example, a sensed position of the driver blade 26 (e.g., based on motor rotational position, a sensor that directly detects the position of the driver blade 26, etc.). If the position of the driver blade 26 is determined to be in the ready position (e.g., BDC) (BLOCK 820), the controller is configured to determine a position of the trigger 720 (BLOCK 815) based on a sensed position of the magnet 716. If the magnet 716 is sensed, the method 800 returns to BLOCK 825 to determine the position of the trigger 720. If the magnet 716 is not sensed, the trigger 720 is determined to be depressed at BLOCK 830, the controller 304 generates a command to release the driver blade 26 (BLOCK 835).

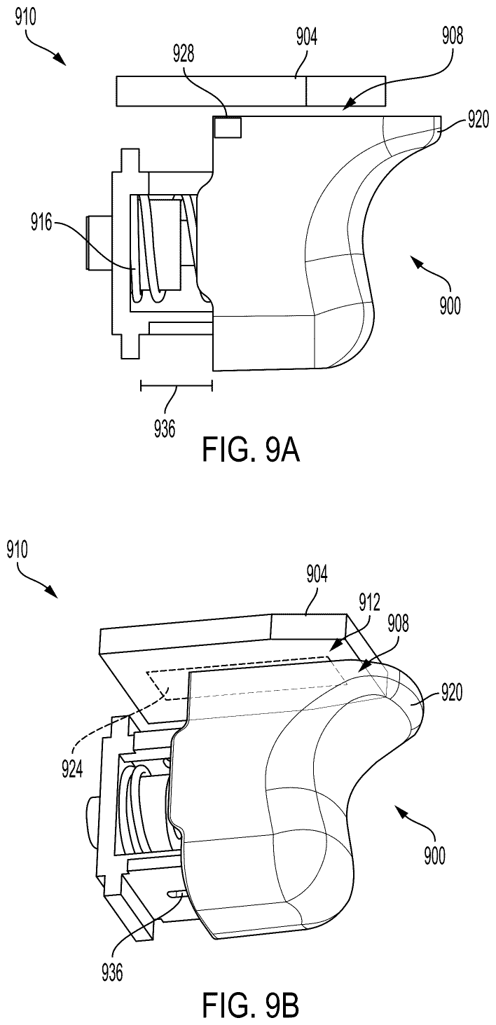

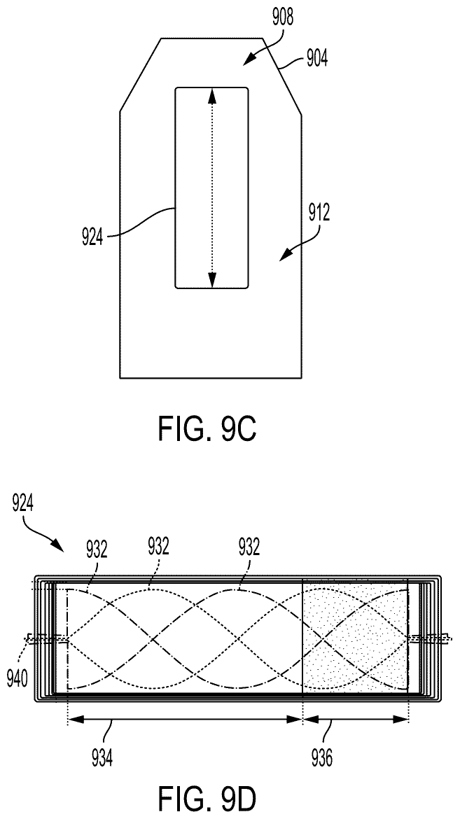

FIGS. 9A and 9B show a user interface 900 for a power tool 910 (e.g., power tool 10). The user interface 900 includes a circuit board 904 and a trigger 920 (e.g., trigger 320) of the power tool 910. The trigger 920 is disposed adjacent to a first side or bottom side 908 of the circuit board 904 and is configured to be depressed by a user so that the trigger 920 moves (e.g., linearly) with respect to the circuit board 904. A trigger return spring 916 is configured to return the trigger 920 to an undepressed position when the trigger 920 is not being depressed. The trigger 920 includes a target portion 928 (e.g., a metallic target) that can be sensed by a trigger sensing portion 912 of the circuit board 904. Although a non-pivoting trigger is shown (e.g., configured for linear movement), embodiments including pivoting triggers are contemplated.

FIG. 9C illustrates a bottom view of a circuit board 904. The circuit board 904 includes the trigger sensing portion 912 disposed on the first side or bottom side 908 of the circuit board 904. The trigger sensing portion 912 is generally rectangular in shape and its length provides a generally linear path for the target portion 928 of the trigger 920 of the power tool 10 to travel along as the trigger 920 is depressed (e.g., by a user).

FIG. 9D illustrates the trigger sensing portion 912 including an inductive sensor 924 (e.g., including interweaved sinusoidal inductive traces 932). In the embodiment shown, the inductive sensor 924 is configured to sense an induced current as the target portion 928 of the trigger 920 is moved along the length of the sensor 924 (e.g., along the motion range 934). A target length 936 of the sensor 924 may be predetermined so that induced currents sensed in response to the movement of the target portion 928 over, for example, the interweaved sinusoidal inductive traces 932, are predictable. A voltage curve of receiving sinusoidal inductive traces may be produced and used to determine the position of target portion 928 of the trigger 920 as the target portion 928 of the trigger 920 is moved along the inductive sensor 924. The position of the target length 936 may be used to determine the position of the trigger 920. For example, in some embodiments, the inductive sensor includes the target portion 928 (e.g., a metallic sense target) and an oscillation circuit on the circuit board 904. The oscillation circuit includes a magnetic field generating coil and a sensing coil (e.g., traces 932). The magnetic field generating coil generates a high-frequency magnetic field. As the target portion 928 moves toward the magnetic field generating coil, a current is induced in the target portion 928 by the high-frequency magnetic field. As the target portion 928 approaches the oscillation circuit, oscillations in the oscillation circuit are reduced or attenuated. The sensing coil detects this change in oscillation and outputs a detection signal that is related to the proximity of the target portion 928 to the oscillation circuit. The location of the target portion corresponds to an amount of depression of the trigger 920. As shown in FIG. 9D, the inductive sensor 924 may include a lead 940 configured to provide a voltage signal to another component of the power tool 10 (e.g., controller 304) for further processing and control of the power tool 910. In some embodiments, the inductive sensor 924 is connected to the trigger 920 and the target portion 928 is connected to the circuit board 904 or the housing of the power tool 910.

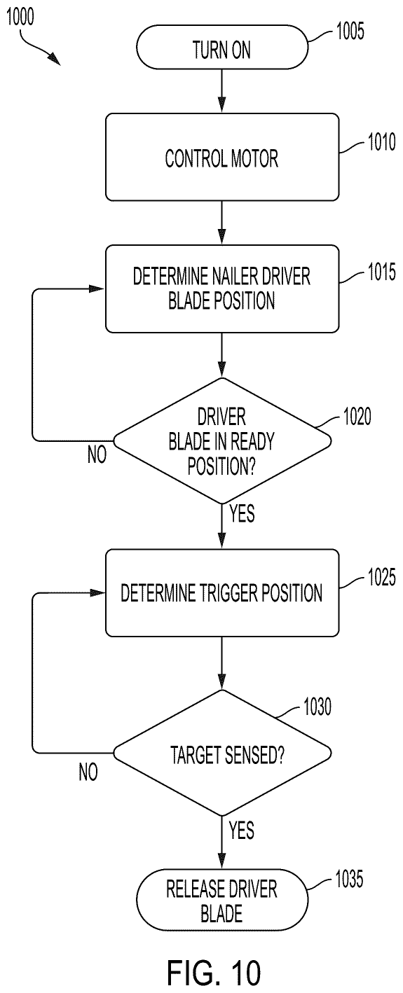

FIG. 10 is a flow chart of a method 1000 for sensing the trigger 920 position for controlling the power tool 910 (e.g., initiating the firing operation of the power tool 10). The method 1000 begins when the power tool 10 is turned on (BLOCK 1005). The controller 304 is configured to execute the method 1000, and begins to control the motor 308 based on power received from the battery pack 12 (BLOCK 1010). In some embodiments, the motor 308 is stationary until a firing operation is initiated. The controller 304 is configured to determine the position of the nailer driver blade 26 (BLOCK 1015) based on, for example, a sensed position of the driver blade 26 (e.g., based on motor rotational position, a sensor that directly detects the position of the driver blade 26, etc.). If the position of the driver blade 26 is determined to be in the ready position (e.g., BDC) (BLOCK 1020), the controller is configured to determine a position of the trigger 920 (BLOCK 1015) based on a sensed position of the target portion 928 using the inductive sensor 924. If an induced current (i.e., eddy current) is not detected by the inductive sensor 924 corresponding to the target portion 928 being in the target length 936 of the sensor 924, the method 1000 returns to BLOCK 1025 to determine the position of the trigger 920. If an induced current is detected by the inductive sensor 924 corresponding to the target portion 928 being in the target length 936 of the sensor 924, the trigger 920 is determined to be depressed at BLOCK 1030, and the controller 304 generates a command to release the driver blade 26 (BLOCK 1035).

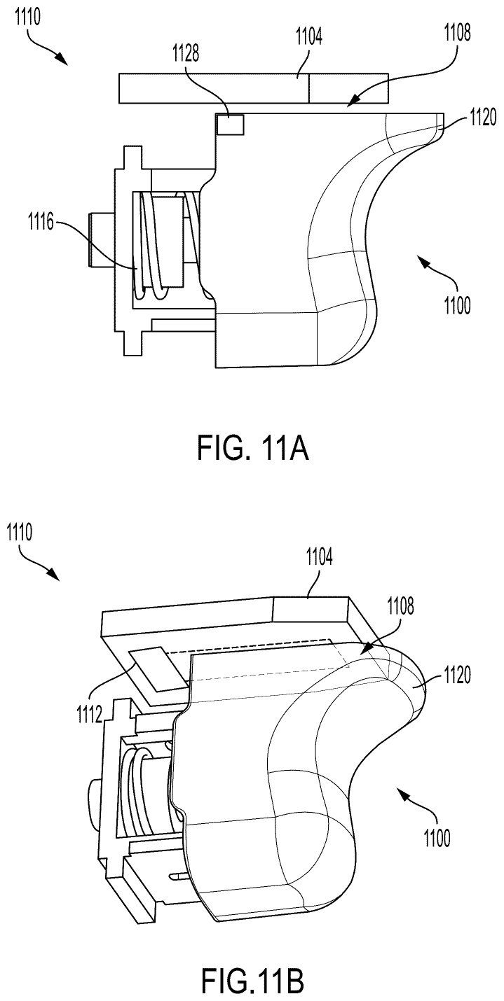

FIGS. 11A and 11B show a user interface 1100 for a power tool 1110 (e.g., power tool 10). The user interface 1100 includes a circuit board 1104 and a trigger 1120 (e.g., trigger 320) of the power tool 1110. The trigger 1120 is disposed adjacent to a first side or bottom side 1108 of the circuit board 1104, and is configured to be depressed by a user so that the trigger 1120 moves (e.g., linearly) with respect to the circuit board 1104. A trigger return spring 1116 is configured to return the trigger 1120 to an undepressed position when the trigger 1120 is not being depressed. The trigger 1120 includes a magnet 1128 that can be sensed by a tunnel magnetoresistance (“TMR”) sensor 1112 on, for example, the circuit board 1104. In some embodiments, the TMR sensor 1112 is mounted on a different circuit board. For example, the TMR sensor 1112 can be mounted on a circuit board positioned behind the trigger 320 such that the printed circuit board and TMR sensor 1112 are positioned perpendicular to an axis of movement of the trigger 1120. In some embodiments, the TMR sensor 1112 detecting the magnet 1128 indicates that the trigger 1120 is being depressed. In other embodiment the TMR sensor 1112 not detecting the magnet 1128 indicates that the trigger 1120 is being depressed. Although a non-pivoting trigger is shown (e.g., configured for linear movement), embodiments including pivoting triggers are contemplated.

The TMR sensor 1112 includes, for example, an insulator layer between a pin ferromagnetic layer and a free ferromagnetic layer. The magnetization direction of the pin ferromagnetic layer is fixed, while the magnetization direction of the free ferromagnetic layer can be changed. A magnetic field generated by the magnet 1128 can interact with the TMR sensor 1112 to control the magnetization direction of the free ferromagnetic layer. When the magnetization directions of the free ferromagnetic layer and the pin ferromagnetic layer are the same, the resistance of the TMR sensor 1112 is at a minimum value. When the magnetization directions of the free ferromagnetic layer and the pin ferromagnetic layer are opposite, the resistance of the TMR sensor 1112 is at a maximum value. By monitoring the resistance of the TMR sensor 1112, actuation of the trigger 1120 can be detected in a non-contact manner using the TMR sensor 1112. In other words, the TMR sensor 1112 is configured to sense a position of the trigger 1120 based on a resistance produced in the TMR sensor 1112 by the magnet 1128. The TMR sensor 1112 may include a lead configured to provide the sensed resistance to another component of the power tool 10 (e.g., controller 304) for further processing. In some embodiments, the TMR sensor 1112 is connected to the trigger 1120 and the magnet 1128 is connected to the circuit board 1104 or the housing of the power tool 1110.

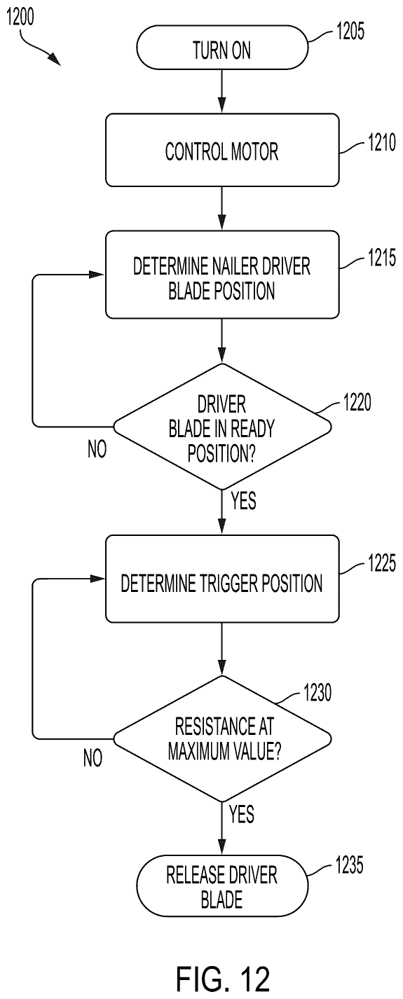

FIG. 12 is a flow chart of a method 1200 for sensing the trigger 1120 position for controlling the power tool 1110 (e.g., initiating the firing operation of the power tool 10). The method 1200 begins when the power tool 10 is turned on (BLOCK 1205). The controller 304 is configured to execute the method 1200, and begins to control the motor 308 based on power received from the battery pack 12 (BLOCK 1210). In some embodiments, the motor 308 is stationary until a firing operation is initiated. The controller 304 is configured to determine the position of the nailer driver blade 26 (BLOCK 1215) based on, for example, a sensed position of the driver blade 26 (e.g., based on motor rotational position, a sensor that directly detects the position of the driver blade 26, etc.). If the position of the driver blade 26 is determined to be in the ready position (e.g., BDC) (BLOCK 1220), the controller is configured to determine a position of the trigger 1120 (BLOCK 1215) based on a sensed resistance of the TMR sensor 1112. If the sensed resistance is at the minimum value, the method 1200 returns to BLOCK 1225 to determine the position of the trigger 1120. If a sensed resistance is at the maximum value, the trigger 1120 is determined to be depressed at BLOCK 1230, and the controller 304 generates a command to release the driver blade 26 (BLOCK 1235). In some embodiments, the sensed resistance being at a minimum value causes the controller 304 to generate a command to release the driver blade 26 at BLOCK 1235.

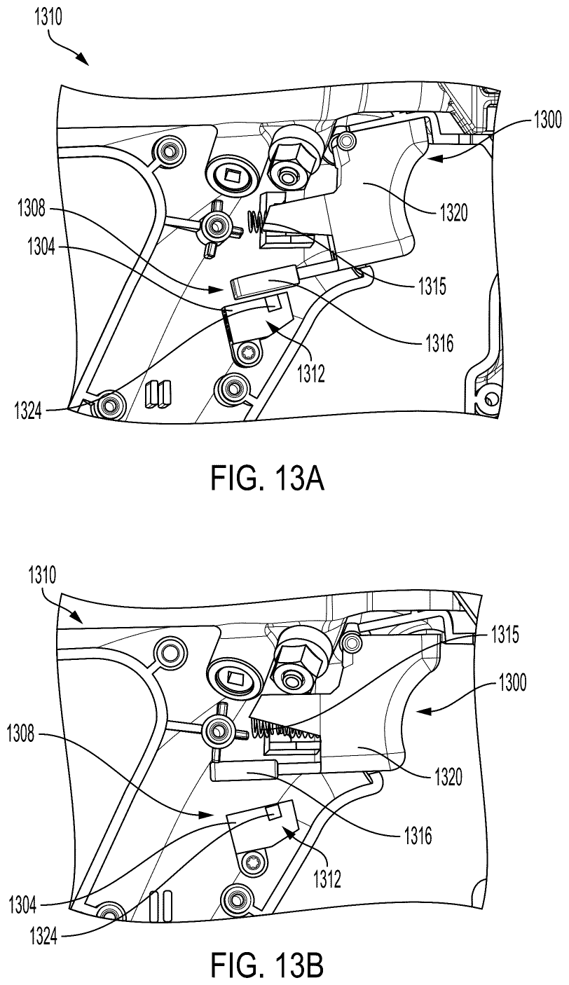

FIGS. 13A and 13B show an embodiment of a user interface 1300 for a power tool 1310 (e.g., power tool 10). The user interface 1300 includes a circuit board 1304 and a trigger 1320 (e.g., trigger 320) of the power tool 1310. The trigger 1320 is disposed adjacent to a side 1308 of the circuit board 1304. When depressed, the trigger 1320 moves a magnet 1316 attached to the trigger 1320 away from the circuit board 1304. A trigger return spring 1315 is configured to return the trigger 1320 to an undepressed position when the trigger 1320 is not being depressed. Although a pivoting trigger is shown, embodiments including non-pivoting triggers (e.g., linear translation triggers) are contemplated.

A sensing portion 1312 is disposed on the circuit board 1304 and includes a magnetic sensor (e.g., a Hall effect sensor) 1324. The trigger 1320 includes the magnet 1316 attached to an outer end of the trigger 1320. The magnetic sensor 1324 is located within the power tool 1310 such that when the trigger 1320 is not actuated, the magnet 1316 is sensed by the magnetic sensor 1324. The magnetic sensor 1324 can be a linear magnetic sensor 1324 that will sense a varying amount of magnetic flux based on the proximity of the magnetic sensor 1324 to the magnet 1316. When the magnetic sensor 1324 does not sense that the magnet 1316 is in close proximity to the magnetic sensor 1324, the magnetic sensor 1324 transmits a signal to the controller 304 to determine that the trigger 1320 is depressed, and a firing operation of the power tool 1310 is initiated. In some embodiments, the magnetic sensor 1324 is a digital Hall effect sensor 1324. The digital Hall effect sensor can output a digital signal (e.g., a pulse-width modulated [“PWM” ] signal) based on the amount of detected magnetic flux from the magnet 1316. In some embodiments, the magnetic sensor 1324 is connected to the trigger 1320 and the magnet 1316 is connected to the circuit board 1304 or the housing of the power tool 1310.

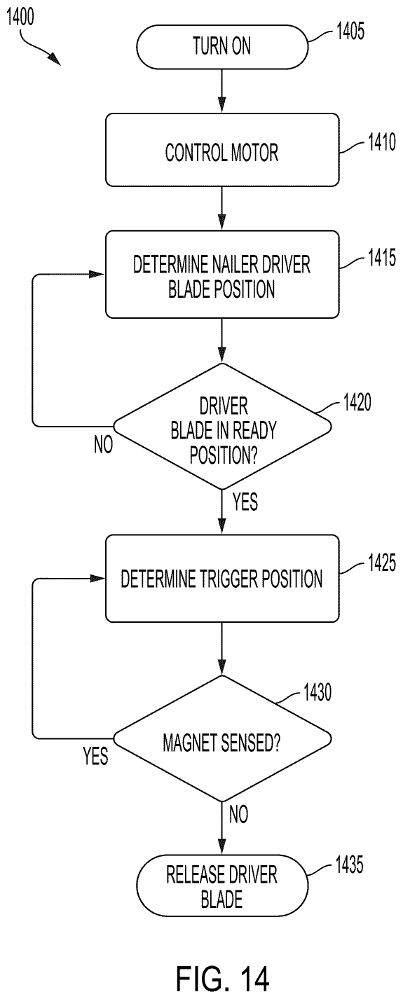

FIG. 14 is a flow chart of a method 1400 for sensing the trigger 1320 position for controlling the power tool 1310 (e.g., initiating the firing operation of the power tool 10). The method 1400 begins when the power tool 10 is turned on (BLOCK 1405). The controller 304 is configured to execute the method 1400, and begins to control the motor 308 based on power received from the battery pack 12 (BLOCK 1410). In some embodiments, the motor 308 is stationary until a firing operation is initiated. The controller 304 is configured to determine the position of the nailer driver blade 26 (BLOCK 1415) based on, for example, a sensed position of the driver blade 26 (e.g., based on motor rotational position, a sensor that directly detects the position of the driver blade 26, etc.). If the position of the driver blade 26 is determined to be in the ready position (e.g., BDC) (BLOCK 1420), the controller is configured to determine a position of the trigger 1320 (BLOCK 1415) based on a sensed position of the magnet 1316. If the magnet 1316 is sensed, the method 1400 returns to BLOCK 1425 to determine the position of the trigger 1320. If the magnet 1316 is not sensed, the trigger 1320 is determined to be depressed at BLOCK 1430, the controller 304 generates a command to release the driver blade 26 (BLOCK 1435).

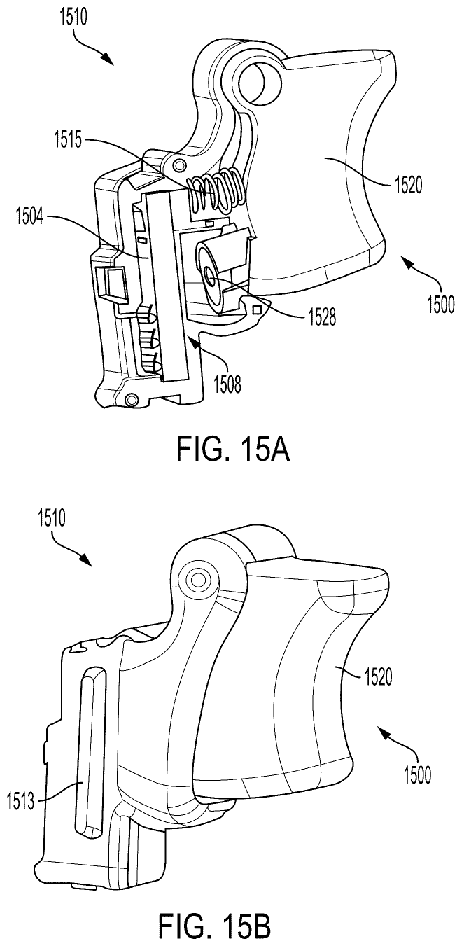

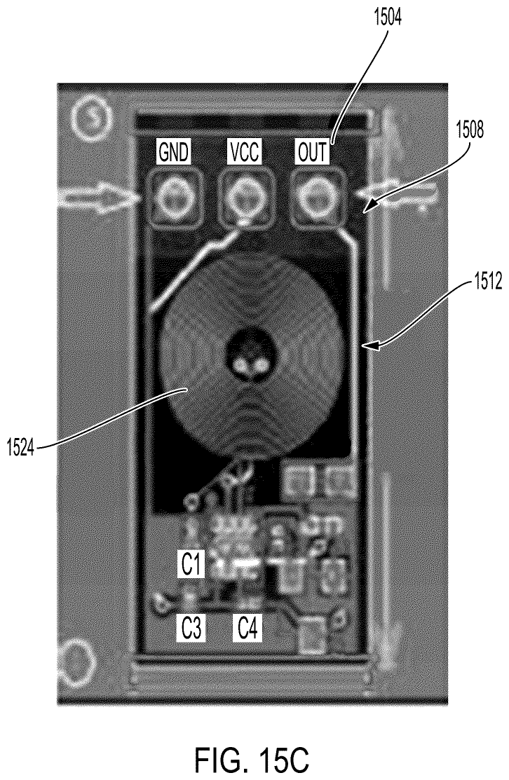

FIGS. 15A and 15B show an embodiment of a user interface 1500 for a power tool 1510 (e.g., power tool 10). The user interface 1500 includes a circuit board 1504 and a trigger 1520 (e.g., trigger 320) of the power tool 1510. The trigger 1520 is disposed adjacent to a first side 1508 of the circuit board 1504 and is configured to be depressed by a user so that the trigger 1520 moves (e.g., pivots) with respect to the circuit board 1504. A trigger return spring 1515 is configured to return the trigger 1520 to an undepressed position when the trigger 1520 is not being depressed. The trigger 1520 includes a target portion 1528 (e.g., a metallic target) that can be sensed by a trigger sensing portion 1512 (see FIG. 15C) of the circuit board 1504. Although a pivoting trigger is shown, in some embodiments, non-pivoting triggers (e.g., linear translation triggers) are included.

FIG. 15C illustrates the trigger sensing portion 1512 including an inductive sensor 1524. In the embodiment shown, the inductive sensor 1524 is a binary induction sensor configured to sense a voltage when the target portion 1528 of the trigger 1520 is moved toward the sensor 1524. In some embodiments, the inductive sensor 1524 functions in the same manner as the inductive sensor 924. A voltage curve may be produced and used to determine the position of target portion 1528 of the trigger 1520 as the target portion 1528 of the trigger 1520 is moved in relation to the inductive sensor 1524. The trigger sensing portion 1512 is located within a housing cover 1513 (see FIG. 15B) of the power tool 1510 such that when the trigger 1520 is actuated, the target portion 1528 is sensed by the inductive sensor 1524. When the inductive sensor 1524 senses that the trigger sensing portion 1512 is in proximity to the inductive sensor, the inductive sensor 1524 is configured to transmit a signal to the controller 304 to indicate that the trigger 1520 is depressed. A firing operation of the power tool 1510 can be initiated. In some embodiments, the inductive sensor 1524 is connected to the trigger 1520 and the target portion 1528 is connected to the circuit board 1504 or the housing of the power tool 1510.

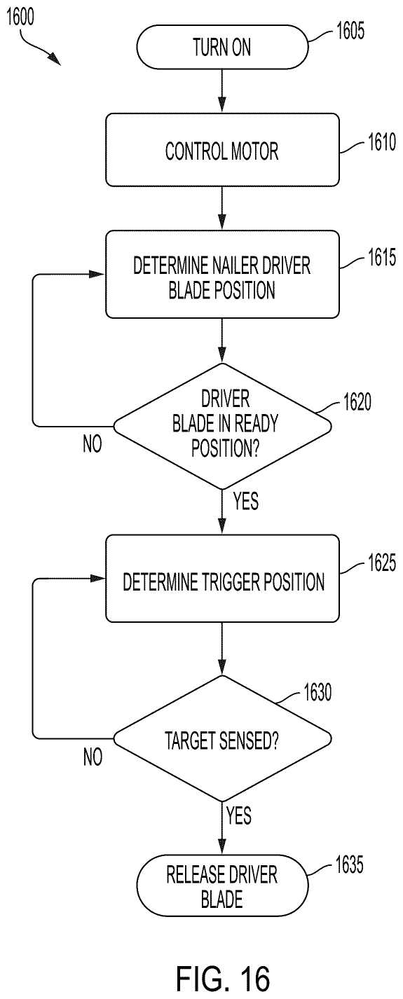

FIG. 16 is a flow chart of a method 1600 for sensing the trigger 1520 position for controlling the power tool 1510 (e.g., initiating the firing operation of the power tool 10). The method 1600 begins when the power tool 1510 is turned on (BLOCK 1605). The controller 304 is configured to execute the method 1600, and begins to control the motor 308 based on power received from the battery pack 12 (BLOCK 1610). In some embodiments, the motor 308 is stationary until a firing operation is initiated. The controller 304 is configured to determine the position of the nailer driver blade 26 (BLOCK 1615) based on, for example, a sensed position of the driver blade 26 (e.g., based on motor rotational position, a sensor that directly detects the position of the driver blade 26, etc.). If the position of the driver blade 26 is determined to be in the ready position (e.g., BDC) (BLOCK 1620), the controller is configured to determine a position of the trigger 1520 (BLOCK 1615) based on a sensed position of the target portion 1528 using the inductive sensor 1524. If an induced current (i.e., eddy current) is not detected by the inductive sensor 1524, the method 1600 returns to BLOCK 1625 to determine the position of the trigger 1520. If an induced current is detected by the inductive sensor 1524, the trigger 1520 is determined to be depressed at BLOCK 1630, and the controller 304 generates a command to release the driver blade 26 (BLOCK 1635).

Thus, embodiments described herein provide systems and methods for implementing sensing of the trigger position for initiating the firing operation of the nailer. Various features and advantages are set forth in the following claims.

What is claimed is:

1. A power tool comprising:
a housing;
a trigger disposed on an outside of the housing, the trigger including a magnet;
a motor within the housing, the motor configured to produce a rotational output to a drive mechanism;
a Hall effect sensor configured to sense a position of the trigger based on a proximity of the magnet to the Hall effect sensor; and
an electronic controller connected to the Hall effect sensor, the electronic controller configured to:
determine the position of the trigger based on a signal from the Hall effect sensor, and
control the drive mechanism based on the position of the trigger.

2. The power tool of claim 1, wherein the position is one of a depressed position or a released position.

3. The power tool of claim 2, wherein the Hall effect sensor is a digital Hall effect sensor.

4. The power tool of claim 2, wherein the Hall effect sensor is configured to sense a varying amount of magnetic flux based on the position of the Hall effect sensor relative to the magnet.

5. The power tool of claim 4, wherein, in response to the trigger being in the depressed position, the electronic controller is configured to control the drive mechanism to initiate a firing operation of the power tool.

6. The power tool of claim 2, wherein, when the trigger is in the depressed position, the Hall effect sensor does not detect the magnet.

7. A power tool comprising:
a housing;
a trigger disposed on an outside of the housing, the trigger including a metal target portion;
a motor within the housing, the motor configured to produce a rotational output to a drive mechanism;
an inductive sensor configured to sense a position of the trigger based on a current induced in the metal target portion by the inductive sensor and generate an output signal; and
an electronic controller connected to the inductive sensor, the electronic controller configured to:
determine the position of the trigger based on the output signal from the inductive sensor, and
control the drive mechanism based on the position of the trigger.

8. The power tool of claim 7, wherein the position of the trigger is one of a depressed position or a released position.

9. The power tool of claim 8, wherein the current is induced in the metal target portion when the trigger is moved to the depressed position.

10. The power tool of claim 9, wherein, in response to the trigger being in the depressed position, the electronic controller controls the power tool to initiate a firing operation of the power tool.

11. The power tool of claim 7, wherein the inductive sensor is disposed on a bottom of a printed circuit board.

12. The power tool of claim 7, wherein the trigger is configured to pivot with respect to the inductive sensor.

13. The power tool of claim 7, wherein the inductive sensor is a binary inductive sensor configured to sense an induced current in response to the metal target portion of the trigger being moved toward the inductive sensor.

14. The power tool of claim 13, wherein, in response to the inductive sensor detecting the induced current, the inductive sensor is configured to transmit a signal to the electronic controller indicating that the trigger is depressed.

15. A power tool comprising:
a housing;
a trigger disposed on an outside of the housing, the trigger including a magnet connected to the trigger;
a motor within the housing, the motor configured to produce a rotational output to a drive mechanism;
a tunnel magnetoresistance (“TMR”) sensor configured to sense a position of the trigger based on a signal produced by the TMR sensor related to a position of the magnet; and
an electronic controller connected to the TMR sensor, the electronic controller configured to:
determine the position of the trigger based on the signal produced by the TMR sensor, and
control the drive mechanism based on the position of the trigger.

16. The power tool of claim 15, wherein the position is one of a depressed position or a released position.

17. The power tool of claim 16, wherein the TMR sensor includes an insulator layer between a pin ferromagnetic layer and a free ferromagnetic layer.

18. The power tool of claim 17, wherein the TMR sensor is configured to sense a first magnetization direction of the pin ferromagnetic layer and a second magnetization direction of the free ferromagnetic layer, and wherein, when the first magnetization direction and the second magnetization direction are opposite, a sensed resistance of the TMR sensor is at a maximum value.

19. The power tool of claim 18, wherein, when the trigger is in the depressed position, the sensed resistance of the TMR sensor is at the maximum value.

20. The power tool of claim 18, wherein the TMR sensor includes a lead configured to provide the sensed resistance to the electronic controller.
